(19) United States
(12) Patent Application Publication
(10) Pub. No.: US 2011/0019117 A1
(43) Pub. Date: Jan. 27, 2011

(54) TFT-LCD ARRAY SUBSTRATE AND MANUFACTURING METHOD THEREOF

(75) Inventors: Hailin XUE, Beijing (CN); Bingqian LIN, Beijing (CN); Yubo XU, Beijing (CN); Cheng LI, Beijing (CN)

Correspondence Address: LADAS & PARRY LLP, 224 SOUTH MICHIGAN AVENUE, SUITE 1600, CHICAGO, IL, 60604, US

(73) Assignee: BEIJING BOE OPTOELECTRONICS TECHNOLOGY CO., LTD., Beijing (CN)

(21) Appl. No.: 12/840,575

(22) Filed: Jul. 21, 2010

(30) Foreign Application Priority Data
Jul. 22, 2009 (CN) 200910089751.4

(51) Int. Cl. G02F 1/136; H01L 21/336

(52) U.S. Cl. 349/47; 438/34; 257/E21.411

(57) ABSTRACT

A thin film transistor liquid crystal display (TFT-LCD) array substrate comprising a first gate line, a second gate line and a data line, which are formed on a substrate and define a pixel region, the first and second gate lines being parallel to each other, a pixel electrode, and a first thin film transistor (TFT) and a second TFT provided in the pixel region. The first TFT comprises a first gate electrode and a first drain electrode, the second TFT comprises a second gate electrode and a second drain electrode, and parasitic capacitance generated between the first drain electrode and the first gate electrode is equal to parasitic capacitance generated between the second drain electrode and the second gate electrode. Both the first drain electrode and the second drain electrode are connected with the pixel electrode. When an “ON” voltage is supplied to the first TFT via the first gate line, a first voltage is supplied to the second TFT via the second gate line; when an “OFF” voltage is supplied to the first TFT via the first gate line, a second voltage is supplied to the second TFT via the second gate line, wherein the “ON” voltage−the “OFF” voltage=the second voltage−the first voltage.

### BACKGROUND

Embodiments of the invention relate to a thin-film transistor liquid crystal display (TFT-LCD) array substrate and a manufacturing method thereof.

TFT-LCDs have the advantages such as small volume, low power consumption, and being free of irradiation and are prevailing in the current flat panel display market. A TFT-LCD mainly comprises an array substrate and a color filter substrate that assembled with each other. Gate lines, data lines, pixel electrodes and thin film transistors are formed on the array substrate, and each pixel electrode is controlled by a corresponding thin film transistor. When the thin film transistor is turned on, the pixel electrode is charged during the “ON” time; after the thin film transistor is turned off, the voltage of the pixel electrode is retained until the pixel electrode is charged again during the next time scanning.

For the single gate structure adopted conventionally, parasitic capacitor Cgd exists in the thin film transistor due to the overlapping between the drain electrode and the gate electrode of the thin film transistor. When the thin film transistor is turned off, the charges Qgd stored due to the parasitic capacitor Cgd is changed, which changes the charge distribution on the pixel electrode. Thus, the voltage applied on the pixel electrode is changed, resulting in occurrence of feed through voltage ΔVp and flickering on the screen. In production, the overlapping areas between the drain electrode and the gate electrode vary at the different locations on a substrate due to the instability of the process and the manufacturing apparatus, which leads to various parasitic capacitors Cgd for different thin film transistors and different feed through voltages for different pixel electrodes. Further, it leads to the irregular distribution of voltage applied on the pixel electrodes and uneven display on the screen, which disadvantageously influences display quality.

### SUMMARY

A thin film transistor liquid crystal display (TFT-LCD) array substrate, comprising a first gate line, a second gate line and a data line which are formed on a substrate and define a pixel region, the first and second gate lines being parallel to each other, a pixel electrode, and a first thin film transistor (TFT) and a second TFT provided in the pixel region. The first TFT comprises a first gate electrode connected with the first gate line and a first drain electrode, the second TFT comprises a second gate electrode connected with the second gate line and a second drain electrode, and parasitic capacitance generated between the first drain electrode and the first gate electrode is equal to parasitic capacitance generated between the second drain electrode and the second gate electrode. Both the first drain electrode and the second drain electrode are connected with the pixel electrode. When an “ON” voltage is supplied to the first TFT via the first gate line, a first voltage is supplied to the second TFT via the second gate line; when an “OFF” voltage is supplied to the first TFT via the first gate line, a second voltage is supplied to the second TFT via the second gate line, wherein the “ON” voltage−the “OFF” voltage=the second voltage−the first voltage.

Another embodiment of the invention provides a manufacturing method for a thin film transistor liquid crystal display (TFT-LCD) comprising: Step 1, depositing a gate metal film on a substrate and patterning the gate metal film so as to form a first gate line, a second gate line, a first gate electrode and a second gate electrode, wherein the first gate electrode is connected with the first gate line, and the second gate electrode is connected with the second gate line; Step 2, depositing a gate insulating layer, an active layer film and a source/drain metal film on the substrate after the step 1, and patterning the active layer film and the source/drain metal film so as to form a first active layer, a second active layer, a data line, a first source electrode, a first drain electrode and a second drain electrode, wherein an overlapping area between the first drain electrode and the first gate electrode being equal to an overlapping area between the second drain electrode and the second gate electrode; Step 3, forming a passivation layer on the substrate after the step 2 and patterning the passivation layer to form a first through hole and a second through hole, wherein the first through hole is located at the position of the first drain electrode, and the second through hole is located at the position of the second drain electrode; Step 4, depositing a transparent conductive film on the substrate after the step 3 and patterning the transparent conductive film to form a pixel electrode, wherein the pixel electrode is connected with the first drain electrode via the first through hole and connected with the second drain electrode via the second through hole.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a plan view of a TFT-LCD array substrate according to a first embodiment of the invention.

FIG. 2 is a cross-sectional view taken along the line A1-A1 in FIG. 1.

FIG. 3 is a cross-sectional view taken along the line B1-B1 in FIG. 1.

FIG. 4 is a plan view of the TFT-LCD array substrate of the first embodiment of the invention after the first patterning process is performed.

FIG. 5 is a cross-sectional view taken along the line A2-A2 in FIG. 4.

FIG. 6 is a cross-sectional view taken along the line B2-B2 in FIG. 4.

FIG. 7 is a plan view of the TFT-LCD array substrate of the first embodiment of the invention after the second patterning process is performed.

FIG. 8 is a cross-sectional view taken along the line A3-A3 in FIG. 7.

FIG. 9 is a cross-sectional view taken along the line B3-B3 in FIG. 7.

FIG. 10 is a plan view of the TFT-LCD array substrate of the first embodiment of the invention after the third patterning process is performed.

FIG. 11 is a cross-sectional view taken along the line A4-A4 in FIG. 10.

FIG. 12 is a cross-sectional view taken along the line B4-B4 in FIG. 10.

FIG. 13 is a plan view of a TFT-LCD array substrate according to a second embodiment of the invention.

FIG. 14 is a cross-sectional view taken along the line C1-C1 in FIG. 13.

FIG. 15 is a cross-sectional view taken along the line D1-D1 in FIG. 13.

FIG. 16 is a plan view of the TFT-LCD array substrate of the second embodiment of the invention after the second patterning process is performed.

FIG. 17 is a cross-sectional view taken along the line C3-C3 in FIG. 16.

FIG. 18 is a cross-sectional view taken along the line D3-D3 in FIG. 16.

FIG. 19 is a plan view of the TFT-LCD array substrate of the second embodiment of the invention after the third patterning process is performed.

FIG. 20 is a cross-sectional view taken along the line C4-C4 in FIG. 19.

FIG. 21 is a cross-sectional view taken along the line D4-D4 in FIG. 19.

FIG. 22 is a plan view of the TFT-LCD array substrate of the second embodiment of the invention after the fourth patterning process is performed.

FIG. 23 is a cross-sectional view taken along the line C5-C5 in FIG. 22.

FIG. 24 is a cross-sectional view taken along the line D5-D5 in FIG. 22.

### DETAILED DESCRIPTION

Hereinafter, the technical solutions according to the embodiments of the invention will be further described in detail.

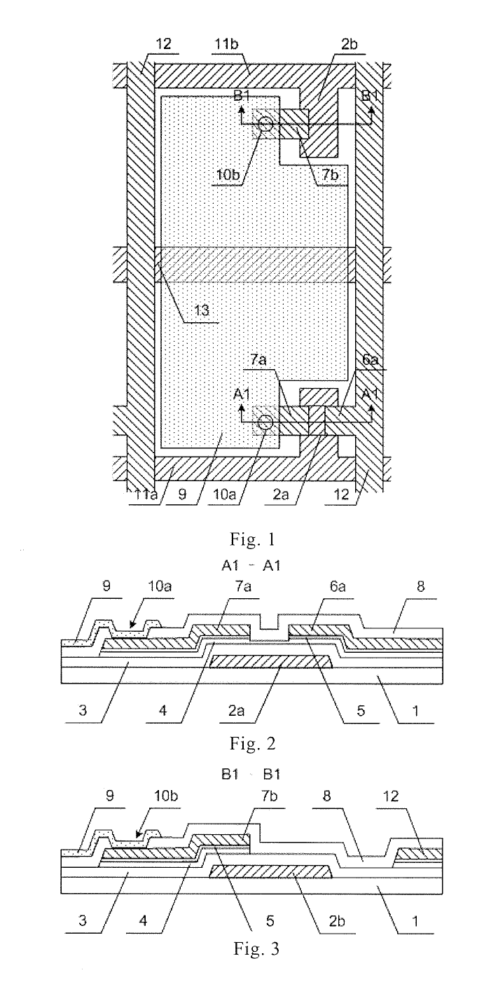

FIG. 1 is a plan view of a TFT-LCD array substrate according to a first embodiment of the invention, showing a structure of one pixel unit. FIG. 2 is a cross-sectional view taken along the line A1-A1 in FIG. 1. FIG. 3 is a cross-sectional view taken along the line B1-B1 in FIG. 1.

As shown in FIGS. 1-3, the array substrate according to the embodiment is one formed by a four-patterning process. The array substrate comprises a first gate line 11a, a second gate line 11b, a data line 12, a pixel electrode 9, a first thin film transistor (TFT) T1 and a second TFT T2, which are formed on, e.g., a transparent substrate 1. The first gate line 11a and the second gate line 11b which are provided in parallel define a pixel region together with the data line 12. The first TFT T1, the second TFT T2 and the pixel electrode 9 are formed in the pixel region. The data line 12 is used to provide data signals for the pixel electrode 9, and first gate line 11a is used as an operative gate line, which is used to provide a first signal including an “ON” voltage and an “OFF” voltage for the first TFT T1, thus the pixel electrode is controlled to receive the data signal by the first TFT T1 used as an operative TFT. The second gate line 11b is used as a compensatory gate line and provides a second signal including a first voltage and a second voltage to the second TFT T2 used as a compensatory TFT. The “ON” voltage−the “OFF” voltage=the second voltage−the first voltage, and in this way the feed through voltage produced in the pixel electrode when the “OFF” voltage is applied on the first gate line 11a can be avoided effectively.

Specifically, the TFT-LCD array substrate according to the embodiment comprises a first gate electrode 2a, a second gate electrode 2b, a first gate line 11a and a second gate line 11b formed on a substrate 1. The first gate electrode 2a is connected with the first gate line 11a, and the second gate electrode 2b is connected with the second gate line 11b. A gate insulating layer 3 is formed on the first gate electrode 2a, the second gate electrode 2b, the first gate line 11a and the second gate line 11b and covers the whole substrate 1. A first active layer and a second active layer (each comprises the stack of a semiconductor layer 4 and a doped semiconductor layer 5) are formed on the gate insulating layer 3, and the first active layer is provided on the first gate electrode 2a, and the second active layer on the second gate electrode 2b. A first source electrode 6a and a first drain electrode 7a are formed on the first active layer. One end of the first source electrode 6a is located over the first gate electrode 2a, and the other end is connected with the data line 12; one end of the first drain electrode 7a is located over the first gate electrode 2a, and the other end is connected with the pixel electrode 9. There is a first overlapping area between the first drain electrode 7a and the first gate electrode 2a. A TFT channel region is formed between the first source electrode 6a and the first drain electrode 7a with the doped semiconductor layer 5 in the TFT channel region being etched away and the semiconductor layer 4 in the region being partially etched in the thickness direction so that the semiconductor layer 4 in the TFT channel region is exposed. A second drain electrode 7b is formed on the second active layer with one end of the second drain electrode 7b being provided above the second gate electrode 2b and the other end being connected with the pixel electrode 9. There is a second overlapping area between the second drain electrode 7b and the second gate electrode 2b, and the second overlapping area is equal to the first overlapping area. A passivation layer 8 is formed on the above structural patterns and covers the whole substrate 1. At the position of the first drain electrode 7a, a first through hole 10a for connection between the first drain electrode 7a and the pixel electrode 9 is provided in the passivation layer 8; at the position of the second drain electrode 7b, a second through hole 10b for connection between the second drain electrode 7b and the pixel electrode 9 is provided in the passivation layer 8. The pixel electrode 9 is formed on the passivation layer 8 and connected with the first drain electrode 7a via the first through hole 10a and connected with the second drain electrode 7b via the second through hole 10b.

In one embodiment, the first voltage may be equal to the “OFF” voltage, and the second voltage may be equal to the “ON” voltage, i.e., when the “ON” voltage is supplied to the first TFT via the first gate line, the “OFF” voltage is supplied to the second TFT via the second gate line; when the “OFF” voltage is supplied to the first TFT via the first gate line, the “ON” voltage is supplied to the second TFT via the second gate line. The design, in which the first and second signals are equal to the “OFF” and “ON” signals respectively, can have the control manner simple and is easy to realize.

In the embodiment, the storage capacitor is formed with a common electrode line (Cs on Common), as shown in the embodiment in FIG. 1. A common electrode line 13 is formed on the substrate 1 so that the pixel electrode 9 and the common electrode line 13 overlap to form a storage capacitor. The feed through voltage ΔVp in the pixel electrode is caused by the parasitic capacitor Cgd formed by overlapping between the gate electrode and the drain electrode. When the “OFF” signal is supplied to the gate line, the charge Qgd stored in the parasitic capacitor is changed. Since the total charge in the pixel capacitor and the parasitic capacitor connected in parallel with each other is kept constant, the change of the stored charge Qgd in the parasitic capacitor leads to the change of the charge distribution across the pixel electrode. Therefore, the voltage applied on the pixel electrode is changed and the feed through voltage is generated in the pixel electrode. The variation of the charge stored in the parasitic capacitor is ΔQgd=Cgd(ΔVp+Vgh−Vgl), wherein Vgh is the “ON” voltage of the gate electrode, Vgl is the “OFF” voltage of the gate electrode, Cgd is the parasitic capacitance, and ΔVp is the feed through voltage generated in the pixel electrode.

Based on analyzing and investigation on the mechanism of generating the feed through voltage in the pixel electrode, the embodiment of the invention employs a pixel structure in which double gate lines and double TFTs are used. The signal difference applied on the first gate line and the second gate line are reversed, i.e., when the “ON” voltage is supplied to the first TFT via the first gate line, the first voltage is supplied to the second TFT via the second gate line; when the “OFF” voltage is supplied to the first TFT via the first gate line, the second voltage is supplied to the second TFT via the second gate line, wherein the “ON” voltage−the “OFF” voltage=the second voltage−the first voltage. Preferably, when the “ON” voltage signal is supplied to the first gate electrode via the first gate line, the “OFF” voltage signal is supplied to the second gate electrode via the second gate line; when the “OFF” voltage signal is supplied to the first gate electrode via the first gate line, the “ON” voltage signal is supplied to the second gate electrode via the second gate line. The operation of the embodiment of the invention will be described in detail with an example in which both the first and second TFTs are applied the “ON” and “OFF” voltage.

When the “OFF” voltage is supplied to the first gate electrode via the first gate line, the amount of the charge stored in the parasitic capacitor of the first TFT before the first TFT is turned off is QAgd(before)=CAgd(VAp−Vgh), the amount of the charge stored in the parasitic capacitor of the first TFT after the first TFT is turned off is QAgd(after)=CAgd(VBp−Vgl), and the variation of the amount of the charge stored in the parasitic capacitor of the first TFT before and after the first TFT is turned off is ΔQAgd=QAgd(after)−QAgd(before)=CAgd[(VBp−Vgl)−(VAp−Vgh)]=CAgd(ΔVp+Vgh−Vgl). Herein, CAgd is the parasitic capacitance of the first TFT, VAp is the pixel electrode voltage before the first TFT is turned off, VBp is the pixel electrode voltage after the first TFT is turned off, and ΔVp=VBp−VAp.

When the “ON” voltage is supplied to the second gate electrode via the second gate line, the amount of the charge stored in the parasitic capacitor of the second TFT before the second TFT is turned on is QBgd(before)=CBgd(VAp−Vgl), the amount of the charge stored in the parasitic capacitor of the second TFT after the second TFT is turned on is QBgd (after)=CBgd(VBp−Vgh), and the variation of the amount of the charge stored in the parasitic capacitor of the second TFT before and after the second TFT is turned on is ΔQBgd=QBgd(after)−QBgd(before)=CBgd[(VBp−Vgh)−(VAp−Vgl)]=CBgd(ΔVp+Vgl−Vgh). Herein, CBgd is the parasitic of the second TFT.

Since the first overlapping area between the first drain electrode and the first gate electrode is equal to the second overlapping area between the second drain electrode and the second gate electrode, the capacitance CAgd of the parasitic capacitor in the first TFT is equal to the capacitance CBgd of the parasitic capacitor in the second TFT, i.e., CAgd=CBgd. Since the charge stored in the pixel capacitor and the parasitic capacitor connected with each other is kept constant, ΔQAgd+ΔQBgd+ΔQC=0, wherein ΔQC is the variation of the amount of the charge before and after the first gate electrode is turned off, ΔQC=(Clc+Cs)(VBp−VAp), Clc is the liquid crystal capacitance, Cs is the storage capacitance. Since the liquid crystal capacitance Clc and the storage capacitance Cs is constant, it will be derived from the above equation that VBp=VAp, and ΔVp=VBp−VAp=0, i.e., the pixel electrode voltage will not be changed before and after the first TFT is turned off. The variation value ΔQAgd of the charge in the parasitic capacitor after the first TFT is turned off is equal to the variation value ΔQBgd of the charge in the parasitic capacitor after the second TFT is turned on, but they are changed in an opposite direction, so that the total variation of the charge in the two parasitic capacitors is 0. The variations of the charge in the two parasitic capacitors counteract with each other and the charge distribution across the pixel electrode will keep constant; therefore, the feed through voltage in the pixel electrode is 0. It can be seen from the above that the variation of the amount of the charge stored in the parasitic capacitor in each TFT is associate with the voltage difference between the first and second voltage signals applied sequentially but not with the voltage values. Therefore, for the second TFT, when the first and second voltages are applied to the second gate electrode via the second gate line, if the difference between the first voltage and the second voltage is predetermined as (Vgl−Vgh), the total variation of the stored charge in the two parasitic capacitors are 0.

It should be noted that the parasitic capacitors are different in size across the substrate, but the two TFTs in the embodiment of the invention are provide in the same pixel region, thus the parasitic capacitance of the two TFT are equal to each other. In addition, the second TFT is formed to provide compensate parasitic capacitance, and it is not a normal TFT with a switch function, but with a structure similar to a normal TFT. Therefore, for the second TFT, it may comprise only a drain electrode connected with a pixel electrode and a gate electrode connected with a gate line, which are located on and below the active layer, respectively, having the same parasitic capacitance as the first TFT; but a source electrode is not necessary for the second TFT.

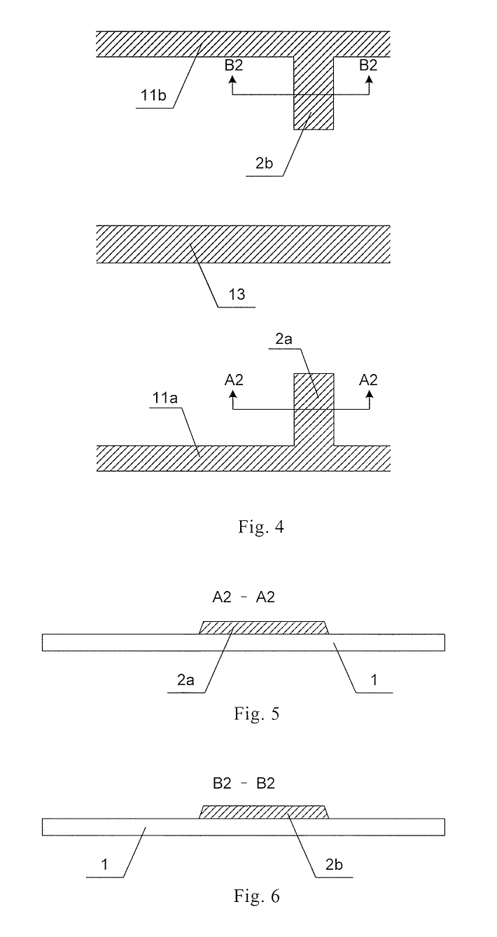

FIGS. 4-12 are schematic views showing the manufacturing process for a TFT-LCD array substrate according to a first embodiment of the invention.

In the following description, the patterning process in the embodiment of the invention may comprise applying photoresist, exposing and developing photoresist, etching and removing remaining photoresist. Herein, positive photoresist is employed as an example.

FIG. 4 is a plan view of the TFT-LCD array substrate according to the first embodiment after the first patterning process is performed, showing a structure of one pixel unit. FIG. 5 is a cross-sectional view taken along the line A2-A2 in FIG. 4, and FIG. 6 is a cross-sectional view taken along the line B2-B2 in the FIG. 4.

First, a gate metal film is deposited on a substrate 1 (e.g., a glass substrate or a silica substrate) by a magnetic sputtering method or a thermal evaporation method, then the patterns including a first gate line 11a, a second gate line 11b, a first gate electrode 2a and a second gate electrode 2b are formed by a patterning process with a normal mask. The first gate electrode 2a is connected with the first gate line 11a, and the second gate electrode 2b is connected with the second gate line 11b, as shown in FIGS. 4-6. In another embodiment, a pattern of a common electrode line 13 may be formed simultaneously.

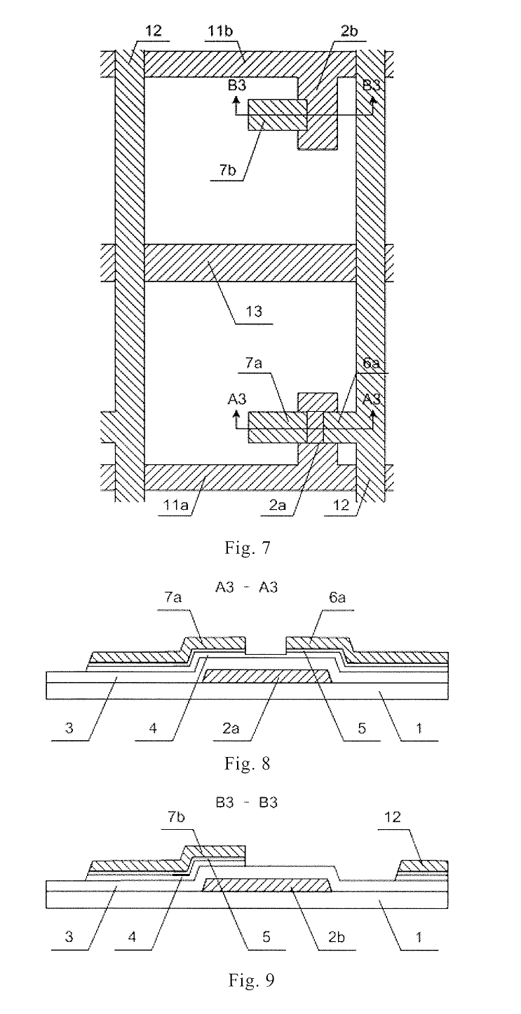

FIG. 7 is a plan view of the TFT-LCD array substrate according to the first embodiment of the invention after the second patterning process is performed, showing a structure of one pixel unit. FIG. 8 is a cross-sectional view taken along the line A3-A3 in FIG. 7, and FIG. 9 is a cross-sectional view taken along the line B3-B3 in FIG. 7.

On the substrate after forming the above structural patterns as shown in FIG. 4, a gate insulating layer, a semiconductor film and a doped semiconductor film are deposited sequentially by a plasma enhanced chemical vapor deposition (PECVD) method, and then a source/drain metal film is deposited by a magnetic sputtering method or a thermal evaporation method. Patterns including a data line 12, a first source electrode 6a, a first drain electrode 7a and a second drain electrode 7b are formed by a pattering process with a half-tone or a grey tone mask, as shown in FIGS. 7-9. The first active layer comprises the stack of a semiconductor layer 4 and a doped semiconductor layer 5, which is formed on the gate insulating layer 3 and located over the first gate electrode 2a. The first source electrode 6a and the first drain electrode 7a are formed on the first active layer. On end of the first source electrode 6a is located over the first gate electrode 2a, and the other end is connected with the data line 12. One end of the first drain electrode 7a is located over the first gate electrode 2a, and has a first overlapping area with the first gate electrode 2a. A TFT channel region is formed between the first source electrode 6a and the first drain electrode 7a, and the doped semiconductor layer 5 in the TFT channel region is etched away and the semiconductor layer 4 is etched partially in the thickness direction, so that the semiconductor layer 4 in the TFT channel region is exposed. The second active layer also comprises the stack of the semiconductor layer 4 and the doped semiconductor layer 5, which is formed on the gate insulating layer 3 and located over the second gate electrode 2b. The second drain electrode 7b is formed on the second active layer. One end of the second drain electrode 7b is located over the second gate electrode 2b and has a second overlapping area with the second gate electrode 2b, and the second overlapping area is equal to the first overlapping area.

The patterning process is a multiple etching step process. Specifically, the gate insulating layer, the semiconductor film and the doped semiconductor film are deposited sequentially, and then the source/drain metal film is deposited. A layer of photoresist is applied on the source/drain metal film. By employing a half-tone or grey-tone mask, an exposure process is performed so that the photoresist is formed into a completely-exposed region, a non-exposed region and a partially-exposed region. The non-exposed region corresponds to the region of the data line, the first source electrode, the first drain electrode and the second drain electrode; the partially-exposed region corresponds to the region of the TFT channel region pattern; and the completely-exposed region corresponds to a region other than the above regions. After developing of the photoresist, the thickness of the photoresist in the non-exposed region is not substantially changed, and the non-exposed region is formed into a photoresist-completely-retained region; the photoresist in the completely-exposed region is removed completely, and the completely-exposed region is formed into a photoresist-completely-removed region; the thickness of the photoresist in the partially-exposed region is reduced and the partially-exposed region is formed into the photoresist-partially-retained region. The patterns including the data line and the second drain electrode are formed by etching away the source/drain metal film, the doped semiconductor film and the semiconductor film in the photoresist-completely-removed region through a first etching process. The photoresist in the photoresist-partially-retained region is removed by an ashing process and the source/drain metal film in the region is exposed, and the photoresist in the photoresist-completely-retained region is left covering the underlying substrate. The source/drain metal film and the doped semiconductor film in the photoresist-partially-retained region is etched away and the semiconductor film in the region is etched partially in the thickness direction through a second etching process, so as to from the patterns including the first source electrode, the first drain electrode and the TFT channel region. Finally, the remaining photoresist is removed and the patterning process is completed.

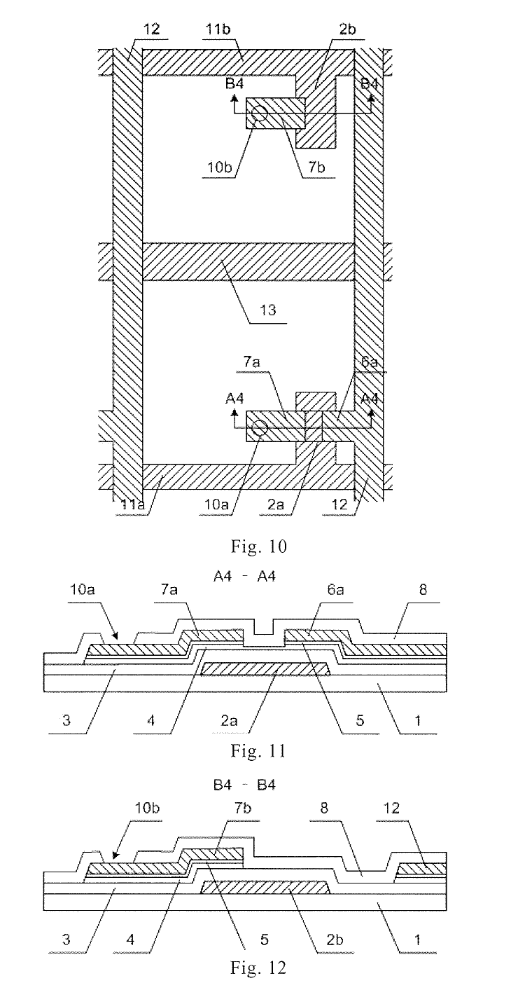

FIG. 10 is a plan view of the TFT-LCD array substrate according to the first embodiment of the invention after a third patterning process is performed, showing a structure of one pixel unit. FIG. 11 is a cross-sectional view taken along the line A4-A4 in FIG. 10, and FIG. 12 is a cross-sectional view taken along the line B4-B4 in FIG. 10.

On the substrate after forming the above patterns as shown in FIG. 7, a passivation layer 8 is deposited by a PECVD method. Patterns including a first through hole 10a and a second through hole 10b are formed in the passivation layer by a patterning process with a normal mask. The first though hole 10a is located at the position of the first drain electrode 7a, and the surface of the first drain electrode 7a is exposed via the first through hole 10a. The second through hole 10b is located at the position of the second drain electrode 7b, and the surface of the second drain electrode 7b is exposed via the second through hole 10b, as shown in FIGS. 10-12. In addition, the patterns of a first gate line pad via hole and a second gate line pad via hole are formed simultaneously in the gate line pad region (gate line PAD) and the pattern of the data line pad via hole is formed in the data line pad region (data line PAD). The process and the structure for the patterning process for foil ling the pad via hole are widely used, description to which is omitted here for simplicity.

Finally, on the substrate after forming the above patterns as shown in FIG. 10, a transparent conductive film is deposited by a magnetic sputtering or a thermal evaporation method, and patterns including a pixel electrode 9 are formed by a patterning process with a normal mask. The pixel electrode 9 is located in the pixel region. It is connected with the first drain electrode 7a via the first through hole 10a. On the other hand, the pixel electrode 9 is connected with the second drain electrode 7b via the second through hole 10b, as shown in FIGS. 1-3.

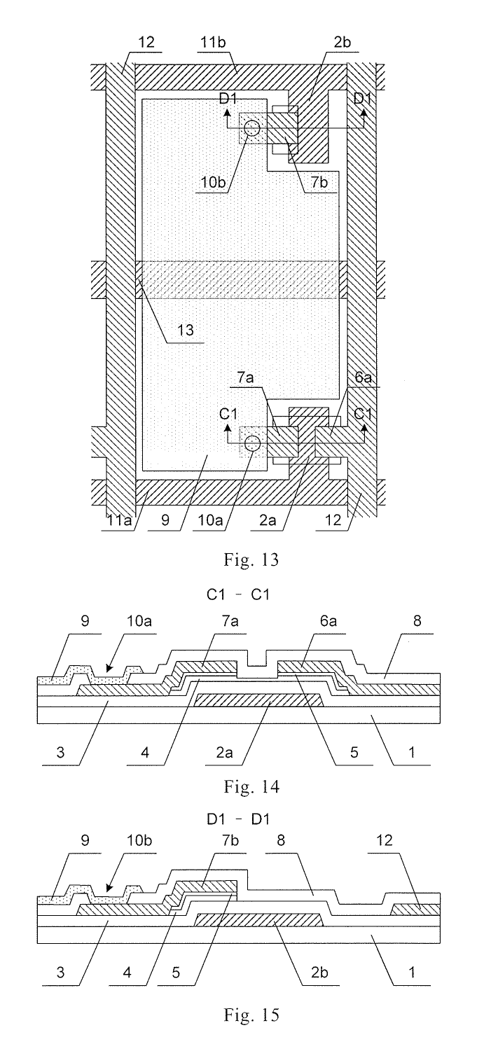

FIG. 13 is a plan view of the TFT-LCD array substrate according to a second embodiment of the invention, showing a structure of one pixel unit. FIG. 14 is a cross-sectional view taken along the line C1-C1 in FIG. 13. FIG. 15 is a cross-sectional view taken along the line D1-D1 in FIG. 13.

As shown in FIGS. 13-15, the TFT-LCD array substrate according to the embodiment is formed by a five-patterning process. The main structures such as the first gate line 11a, the second gate line 11b, the data line 12, the common electrode line 13 and the pixel electrode 9 are the same as those in the first embodiment, and the embodiment is different from the first embodiment in the structure of the first and second TFTs. Specifically, the TFT-LCD array substrate according to the embodiment comprises a first gate electrode 2a, a second gate electrode 2b, a first gate line 11a and a second gate line 11b. The first gate electrode 2a is connected with the first gate line 11a, and the second gate electrode 2b is connected with the second gate line 11b. A gate insulating layer 3 is formed on the first gate electrode 2a, the second gate electrode 2b, the first gate line 11a and the second gate line 11b and covers the whole substrate 1. A first active layer and a second active layer (each comprises a semiconductor layer 4 and a doped semiconductor layer 5) are formed on the gate insulating layer 3. The first active layer is located over the first gate electrode 2a, and the second active layer is located over the second gate electrode 2b. One end of the first source electrode 6a is located on the first active layer, and the other end is connected with the data line 12. One end of the first drain electrode 7a is located on the first active layer, and the other end is connected with the pixel electrode 9. The first drain electrode 7a and the first gate electrode 2a have a first overlapping area. A TFT channel region is formed between the first source electrode 6a and the first drain electrode 7a. The doped semiconductor layer 5 in the TFT channel region is etched away, and the semiconductor layer 4 in the region is etched partially in the thickness direction, so that the semiconductor layer 4 in the region is exposed. One end of the second drain electrode 7b is located on the second active layer, the other end is connected with the pixel electrode 9. The second drain electrode 7b and the second gate electrode 2b have a second overlapping area, and the second overlapping area is equal to the first overlapping area. A passivation layer 8 is formed on the above patterns and covers the whole substrate 1. At the position of the first drain electrode 7a, a first through hole 10a for connection between the first drain electrode 7a and the pixel electrode 9 is provided in the passivation layer 8; at the position of the second drain electrode 7b, a second through hole 10b for connection between the second drain electrode 7b and the pixel electrode 9 is provided in the passivation layer 8. The pixel electrode 9 is formed on the passivation layer 8 and connected with the first drain electrode 7a via the first through hole 10a and connected with the second drain electrode 7b via the second through hole 10b.

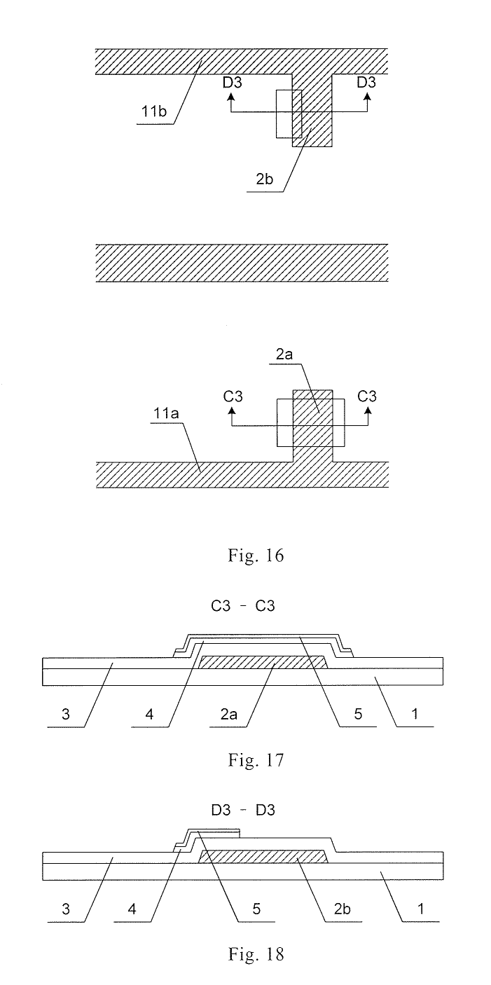

FIGS. 16-24 are schematic views showing a manufacturing method for the TFT-LCD array substrate according to the second embodiment of the invention. The first patterning process in the embodiment is to form patterns including the first gate line 11a, the second gate line 11b, the first gate electrode 2a and the second gate electrode 2b, the process and the structure of which are the same as those in the first embodiment shown in FIGS. 4-6.

FIG. 16 is a plan view of the TFT-LCD array substrate after the second patterning process according to a second embodiment of the invention, showing a structure of one pixel unit. FIG. 17 is a cross-sectional view taken along the line C3-C3 in FIG. 16. FIG. 18 is a cross-sectional view taken along the line D3-D3 in FIG. 16.

A gate insulating layer, a semiconductor film and a doped semiconductor film are deposited sequentially by a PECVD method on the substrate with the patterns including the first gate line, the second gate line, the first gate electrode and the second gate electrode, the patterns including a first active layer and a second active layer are formed by a patterning process with a normal mask, as shown in FIGS. 16-18. The first active layer comprises the stack of a semiconductor layer 4 and a doped semiconductor layer 5, and it is formed on the gate insulating layer 3 and located over the first gate electrode 2a. The second active layer also comprises the stack of the semiconductor layer 4 and the doped semiconductor layer 5, and it is formed on the gate insulating layer 3 and located over the second gate electrode 2b. In the embodiment, the second active layer may only be formed over the second drain electrode, i.e., the second active layer is located over one side of the second gate electrode near the pixel electrode.

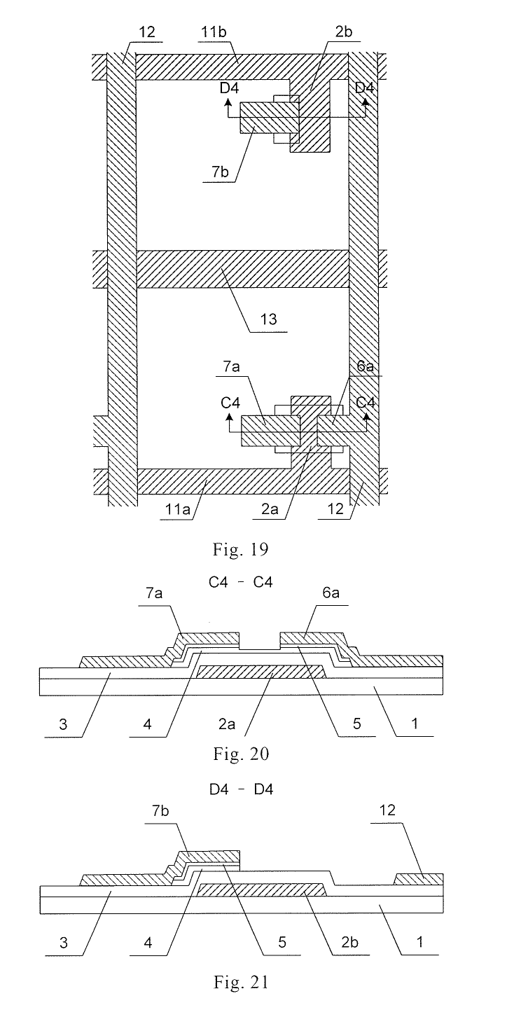

FIG. 19 is a plan view of the TFT-LCD array substrate after the third patterning process according to a second embodiment of the invention, showing a structure of one pixel unit. FIG. 20 is a cross-sectional view taken along the line C4-C4 in FIG. 19. FIG. 21 is a cross-sectional view taken along the line D4-D4 in FIG. 19.

On the substrate with the above patterns as shown in FIG. 16, a source/drain metal film is deposited by a magnetic sputtering or thermal evaporation method, and patterns including a data line 12, a first source electrode 6a, a first drain electrode 7a, and a second drain electrode 7b are formed by a patterning process with a normal mask, as shown in FIGS. 19-21. One end of the first source electrode 6a is located on the first active layer, and the other end is connected with the data line 12; one end of the first drain electrode 7a is located on the first active layer and has a first overlapping area with the first gate electrode 2a. A TFT channel region is formed between the first source electrode 6a and the first drain electrode 7a with the doped semiconductor layer 5 in the TFT channel region being etched away and the semiconductor layer 4 in the region being partially etched so that the semiconductor layer 4 in the TFT channel region is exposed. One end of the second drain electrode 7b is formed on the second active layer and has a second overlapping area with the second gate electrode 2b, and the second overlapping area is equal to the first overlapping area.

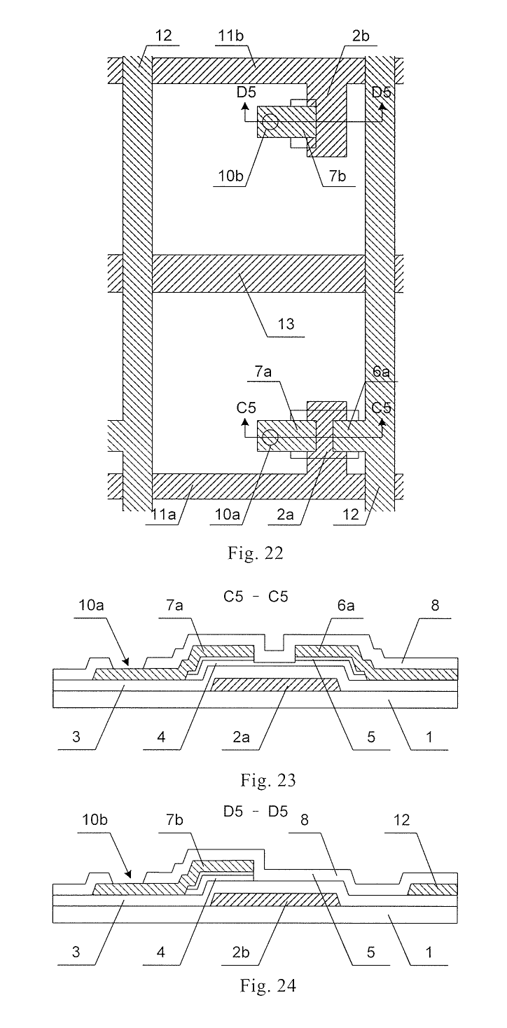

FIG. 22 is a plan view of the TFT-LCD array substrate after the fourth patterning process according to a second embodiment of the invention, showing a structure of one pixel unit. FIG. 23 is a cross-sectional view taken along the line C5-C5 in FIG. 22. FIG. 24 is a cross-sectional view taken along the line D5-D5 in FIG. 22.

On the substrate after forming the above patterns as shown in FIG. 19, a passivation layer 8 is deposited by a PECVD method. Patterns including a first through hole 10a and a second through hole 10b are formed in the passivation layer by a patterning process with a normal mask. The first though hole 10a is located at the position of the first drain electrode 7a, and the surface of the first drain electrode 7a is exposed via the first through hole 10a. The second through hole 10b is located at the position of the second drain electrode 7b, and the surface of the second drain electrode 7b is exposed via the second through hole 10b, as shown in FIGS. 22-24. In the patterning process, the patterns of the gate line pad via hole and the data line pad via hole may be formed simultaneously.

Finally, on the substrate after forming the above patterns as shown in FIG. 22, a transparent conductive film is deposited by a magnetic sputtering or a thermal evaporation method, and patterns including a pixel electrode 9 are formed by a patterning process with a normal mask. The pixel electrode 9 is located in the pixel region. The pixel electrode 9 is connected with the first drain electrode 7a via the first through hole 10a. On the other hand, the pixel electrode 9 is connected with the second drain electrode 7b via the second through hole 10b, as shown in FIGS. 13-15.

It can be seen from the above that the second embodiment uses two patterning processes instead of one patterning process (the second patterning process) with a half-tone or grey tone mask in the first embodiment. That is to say, one patterning process with a normal mask is used to form the patterns including the first active layer and the second active layer, and another patterning process with a normal mask is used to form the patterns of the data line, the first source electrode, the first drain electrode and the second drain electrode.

It can be seen from the above embodiments that the TFT-LCD array substrate according to the embodiment of the invention enables the constant total charge amount when the pixel electrode is charged completely and eliminates the feed through voltage in the pixel electrode by employing double gate lines and double TFTs with equal parasitic capacitance. The technical solution according to the embodiment of the invention not only has the advantages such as simple structure and high yield but also is easy to be implemented and does not increase the production and manufacturing cost. The technical solution is suitable for the large size liquid crystal display and has a wide application prospective.

A manufacturing method for the TFT-LCD array substrate according to the embodiment of the invention may comprise the following steps.

Step 1, depositing a gate metal film on a substrate and patterning the gate metal film so as to form a first gate line, a second gate line, a first gate electrode and a second gate electrode, wherein the first gate electrode is connected with the first gate line, and the second gate electrode is connected with the second gate line;

Step 2, depositing a gate insulating layer, a active layer film and a source/drain metal film on the substrate after the step 1, and patterning the active layer film and the source/drain metal film so as to form a first active layer, a second active layer, a data line, a first source electrode, a first drain electrode and a second drain electrode, wherein the overlapping area between the first drain electrode and the first gate electrode is equal to that between the second drain electrode and the second gate electrode;

Step 3, forming a passivation layer on the substrate after the step 2 and patterning the passivation layer to form a first through hole and a second through hole, wherein the first through hole is located at the position of the first drain electrode, and the second through hole is located at the position of the second drain electrode;

Step 4, forming a transparent conductive film on the substrate after the step 3 and patterning the transparent conductive film to form a pixel electrode, wherein the pixel electrode is connected with the first drain electrode via the first through hole and connected with the second drain electrode via the second through hole.

This embodiment of the invention provides a manufacturing method for a TFT-LCD array substrate, which enables the constant total charge amount when the pixel electrode is charged completely and eliminates the feed through voltage in the pixel electrode by forming double gate lines and double TFTs with equal parasitic capacitance. The embodiment of the invention not only has the advantages such as simple structure and notable yield but also is easy to be implemented and does not increase the production and manufacturing cost. The technical solution is suitable for the large size liquid crystal displayer and has a wide application prospective.

The manufacturing method for the TFT-LCD array substrate according to the embodiment of the invention is further described with the following specific examples.

The manufacturing method for the TFT-LCD array substrate according to the first example of the invention comprises the following steps.

Step 11, depositing a gate metal film on a substrate by a magnetic sputtering or thermal evaporation method and forming patterns including a first gate line, a second gate line, a first gate electrode and a second gate electrode by a patterning process, wherein the first gate electrode is connected with the first gate line, and the second gate electrode is connected with the second gate line;

Step 12, depositing a gate insulating layer, a semiconductor film, a doped semiconductor film sequentially by a plasma enhanced chemical vapor deposition method and depositing a source/drain metal film by a magnetic sputtering or thermal evaporation method;

Step 13, applying a layer of photoresist on the source/drain metal film; exposing the photoresist with a half-tone or grey-tone mask so as to transform the photoresist into a photoresist-completely-removed region, a photoresist-completely-retained region and a photoresist-partially-retained region, wherein the photoresist-completely-retained region corresponds to the region of the data line, the first source electrode, the first drain electrode and the second drain electrode, the photoresist-partially-retained region corresponds to the TFT channel region, and the photoresist-completely-removed region corresponds a region other than the above regions, and after developing of the photoresist, the thickness of the photoresist in the photoresist-completely-retained region remains unchanged, the photoresist in the photoresist-completely-removed region is removed completely, and the thickness of the photoresist-partially-retained region is reduced;

Step 14, etching away the source/drain metal film, the doped semiconductor film and the semiconductor film in the photoresist-completely-retained region by a first etching process, so as to form the data line and the second drain electrode;

Step 15, removing the photoresist in the photoresist-partially-retained region by an ashing process so that the source/drain electrode in the region is exposed and the photoresist in the photoresist-completely-retained region is thinned correspondingly;

Step 16, etching away the source/drain metal film and the doped semiconductor film in the photoresist-partially-retained region and etching the semiconductor film in the region partially in the thickness direction by a second etching process, so as to form patterns including the first source electrode, the first drain electrode and the TFT channel region, wherein the overlapping area between the first drain electrode and the first gate electrode is equal to the overlapping area between the second drain electrode and the second gate electrode; removing the remaining photoresist;

Step 17, depositing a passivation layer by a plasma enhance chemical vapor deposition method and forming the patterns including a first through hole and a second through hole in the passivation layer by a patterning process with a normal mask, wherein the first though hole is located at the position of the first drain electrode, and the second through hole is located at the position of the second drain electrode;

Step 18, depositing a transparent conductive film by a magnetic sputtering method and a thermal evaporation method and forming a pixel electrode by a patterning process with a normal mask, wherein the pixel electrode is connected with the first drain electrode via the first through hole and connected with the second drain electrode via the second through hole.

This example is a method for manufacturing the TFT-LCD array substrate by a four-patterning process, and the process has been described in detailed with reference to FIGS. 4-12.

The second example of the manufacturing method for the TFT-LCD array substrate comprises the following steps.

Step 21, depositing a gate metal film on a substrate and forming patterns including a first gate line, a second gate line, a first gate electrode and a second gate electrode by a patterning process, wherein the first gate electrode is connected with the first gate line, and the second gate electrode is connected with the second gate line;

Step 22, depositing a gate insulating layer, a semiconductor film and a doped semiconductor film sequentially by a plasma enhanced chemical vapor deposition;

Step 23, forming patterns including a first active layer and a second active layer by a patterning process with a normal mask;

Step 24, depositing a source/drain metal film by a magnetic sputtering or thermal evaporation method;

Step 25, forming patterns including a data line, a first source electrode, a first drain electrode, a TFT channel region and a second drain electrode by a patterning process with a normal mask, wherein the overlapping area between the first drain electrode and the first gate electrode is equal to the overlapping area between the second drain electrode and the second gate electrode;

Step 26, depositing a passivation layer by a plasma enhance chemical vapor deposition method and forming patterns including a first through hole and a second through hole in the passivation layer by a patterning process with a normal mask, wherein the first though hole is located at the position of the first drain electrode, and the second through hole is located at the position of the second drain electrode.

Step 27, depositing a transparent conductive film by a magnetic sputtering method and a thermal evaporation method and forming a pixel electrode by a patterning process with a normal mask, wherein the pixel electrode is connected with the first drain electrode via the first through hole and connected with the second drain electrode via the second through hole.

The example is a method of manufacturing the TFT-LCD array substrate by a five-patterning process, and the specific process has been described in detail with reference to FIGS. 16-24.

On the basis of the above examples, a common electrode line can be further provided. In this example, Step 1 can comprise depositing a gate metal film on a substrate and forming patterns including a first gate line, a second gate line, a first gate electrode, a second gate electrode and a common electrode line by a patterning process. The first gate electrode is connected with the first gate line, and the second gate electrode is connected with the second gate line.

The invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. A thin film transistor liquid crystal display (TFT-LCD) array substrate comprising:
a first gate line, a second gate line and a data line, which are formed on a substrate and define a pixel region, the first and second gate lines being parallel to each other,
a pixel electrode, and
a first thin film transistor (TFT) and a second TFT provided in the pixel region, the first TFT comprising a first gate electrode connected with the first gate line and a first drain electrode, the second TFT comprising a second gate electrode connected with the second gate line and a second drain electrode,
wherein parasitic capacitance generated between the first drain electrode and the first gate electrode is equal to parasitic capacitance generated between the second drain electrode and the second gate electrode, and both the first drain electrode and the second drain electrode are connected with the pixel electrode,
wherein when an “ON” voltage is supplied to the first TFT via the first gate line, a first voltage is supplied to the second TFT via the second gate line; when an “OFF” voltage is supplied to the first TFT via the first gate line, a second voltage is supplied to the second TFT via the second gate line, and
wherein the “ON” voltage−the “OFF” voltage=the second voltage−the first voltage.

2. The TFT-LCD array substrate of claim 1, wherein the first voltage is equal to the “OFF” voltage, and the second voltage is equal to the “ON” voltage.

3. The TFT-LCD array substrate of claim 1, wherein the first TFT further comprises a first active layer, a first source electrode and a TFT channel region, the first drain electrode and the first gate electrode has a first overlapping area; and
the second TFT further comprises a second active layer, and the second drain electrode and the second gate electrode have a second overlapping area, and the first overlapping area is equal to the second overlapping area.

4. The TFT-LCD array substrate of claim 3, wherein the first gate electrode is formed on the substrate and connected with the first gate line with a gate insulating layer covered thereon; the first active layer is formed on the gate insulating layer and located over the first gate electrode; one end of the first source electrode is located above the first gate electrode, and the other end is connected with the data line; one end of the first drain electrode is located above the first gate electrode, and the other end is connected with the pixel electrode; the TFT channel region is formed between the first source electrode and the first drain electrode; the first source electrode, the first drain electrode and the TFT channel region are covered with a passivation layer, and a first through hole is provided in the passivation layer at the position of the firs drain electrode for connecting the first drain electrode and the pixel electrode.

5. The TFT-LCD array substrate of claim 4, wherein the first active layer comprises the stack of a semiconductor layer and a doped semiconductor layer, the doped semiconductor layer in the TFT channel region is etched away, and the semiconductor layer in the region is etched partially in the thickness direction, so that the semiconductor layer in the TFT channel region is exposed.

6. The TFT-LCD array substrate of claim 4, wherein the second gate electrode is formed on the substrate and connected with the second gate line, also covered with the gate insulating layer; the second active layer is formed on the gate insulating layer and located over the second gate electrode; one end of the second drain electrode is located above the second gate electrode, the other end is connected with the pixel electrode; the second drain electrode is covered with the passivation layer provided with a second through hole at the position of the second drain electrode for connecting the second drain electrode and the pixel electrode.

7. The TFT-LCD array substrate of claim 6, wherein the second active layer comprises the stack of a semiconductor layer and a doped semiconductor layer.

8. The TFT-LCD array substrate of claim 1, further comprising a common electrode line formed on the substrate, and the common electrode line and the pixel electrode overlap each other to form a storage capacitor.

9. The TFT-LCD array substrate of claim 2, wherein the first drain electrode and the first gate electrode have a first overlapping area, the second drain electrode and the second gate electrode have a second overlapping area, and the first and the second overlapping areas are equal to each other.

10. A manufacturing method for a thin film transistor liquid crystal display (TFT-LCD) comprising,
Step 1, depositing a gate metal film on a substrate and patterning the gate metal film so as to form a first gate line, a second gate line, a first gate electrode and a second gate electrode, wherein the first gate electrode is connected with the first gate line, and the second gate electrode is connected with the second gate line;
Step 2, depositing a gate insulating layer, an active layer film and a source/drain metal film on the substrate after the step 1, and patterning the active layer film and the source/drain metal film so as to form a first active layer, a second active layer, a data line, a first source electrode, a first drain electrode and a second drain electrode, wherein an overlapping area between the first drain electrode and the first gate electrode being equal to an overlapping area between the second drain electrode and the second gate electrode;
Step 3, forming a passivation layer on the substrate after the step 2 and patterning the passivation layer to form a first through hole and a second through hole, wherein the first through hole is located at the position of the first drain electrode, and the second through hole is located at the position of the second drain electrode; and
Step 4, depositing a transparent conductive film on the substrate after the step 3 and patterning the transparent conductive film to form a pixel electrode, wherein the pixel electrode is connected with the first drain electrode via the first through hole and connected with the second drain electrode via the second through hole.

11. The manufacturing method of claim 10, wherein the step 2 comprises,
depositing the gate insulating layer, a semiconductor film, a doped semiconductor film and the source/drain metal film sequentially, wherein the active layer film is formed by the stack of the semiconductor film and the doped semiconductor film;
applying a layer of photoresist on the source/drain metal film;
performing exposure with a half-tone or grey-tone mask so as to make the photoresist formed into a photoresist-completely-removed region, a photoresist-completely-retained region and a photoresist-partially-retained region, wherein the photoresist-completely-retained region corresponds to the region of the data line, the first source electrode, the first drain electrode and the second drain electrode, the photoresist-partially-retained region corresponds to the TFT channel region, the photoresist-completely-removed region corresponds a region other than the above regions, and after developing, the thickness of the photoresist in the photoresist-completely-retained region remains unchanged, the photoresist in the photoresist-completely-removed region is removed, and the thickness of the photoresist-partially-retained region is reduced;
etching away the source/drain metal film, the doped semiconductor film and the semiconductor film in the photoresist-completely-retained region by a first etching process, so as to form the data line and the second drain electrode;
removing the photoresist in the photoresist-partially-retained region by an ashing process so that the source/drain electrode in the region is exposed and the photoresist in the photoresist-completely-retained region is thinned;
etching away the source/drain metal film and the doped semiconductor film in the photoresist-partially-retained region, and etching the semiconductor film in the region partially in the thickness direction, so as to form the first source electrode, the first drain electrode and the TFT channel region; and
removing the remaining photoresist.

12. The manufacturing method of claim 10, wherein the step 2 comprises,
depositing the gate insulating layer, a semiconductor film and a doped semiconductor film sequentially, wherein the active layer film is formed by the stack of the semiconductor film and the doped semiconductor film;
forming the first active layer and the second active layer by a patterning process with a normal mask;
depositing the source/drain metal film; and
forming the data line, the first source electrode, the first drain electrode, the TFT channel region and the second drain electrode by a patterning process with a normal mask.

13. The manufacturing method of claim 10, wherein, in the step 1, a common electrode line is formed, and the common electrode line and the pixel electrode formed later overlap each other to form a storage capacitor.

14. The manufacturing method of claim 11, wherein, in the step 1, a common electrode line is formed, and the common electrode line and the pixel electrode formed later overlap each other to form a storage capacitor.

15. The manufacturing method of claim 12, wherein, in the step 1, a common electrode line is formed, and the common electrode line and the pixel electrode formed later overlapped with each other to form a storage capacitor.
